(19) United States
(12) Patent Application Publication
(10) Pub. No.: US 2022/0035238 A1
(43) Pub. Date: Feb. 3, 2022

(54) PHOTOLITHOGRAPHY ALIGNMENT METHOD AND SYSTEM

(71) Applicant: CHANGXIN MEMORY TECHNOLOGIES, INC., Hefei City (CN)

(72) Inventor: Lei ZHAO, Hefei City (CN)

(73) Assignee: CHANGXIN MEMORY TECHNOLOGIES, INC., Hefei City (CN)

(21) Appl. No.: 17/451,404

(22) Filed: Oct. 19, 2021

Related U.S. Application Data
(63) Continuation of application No. PCT/CN2021/098804, filed on Jun. 8, 2021.

(30) Foreign Application Priority Data
Jul. 31, 2020 (CN) 202010762535.8

(51) Int. Cl. G03F 1/42; G01B 11/27; G03F 1/70; H01L 21/66; H01L 21/68; H01L 23/544

(52) U.S. Cl. CPC G03F 1/42; G01B 11/272; G03F 1/70; H01L 2223/54426; H01L 21/682; H01L 23/544; H01L 22/12

(57) ABSTRACT

A photolithography alignment method includes: performing alignment measurement of a surface condition of a wafer to obtain alignment information of the wafer; and sectioning the wafer into a plurality of areas to be processed according to the alignment information, and determining photolithography alignment parameters corresponding to each area to be processed.

### CROSS-REFERENCE TO RELATED APPLICATIONS

The present disclosure is a US continuation application of International Application No. PCT/CN 2021/098804 filed on Jun. 8, 2021, which claims priority to Chinese Application No. 202010762535.8, filed on Jul. 31, 2020 and entitled “PHOTOLITHOGRAPHY ALIGNMENT METHOD AND SYSTEM”. The disclosures of these applications are hereby incorporated by reference in their entirety.

### BACKGROUND

In a production process of processing a wafer into chips, processes such as photolithography, treatment, chemical mechanical polishing, ion doping, etc. will be carried out. Any of the processes may cause differences in surface conditions in different areas of the wafer, such as differences in the heights of the wafer surface, differences in the depths of the embedded patterns, and differences in the symmetry of the patterns.

### SUMMARY

The disclosure relates to a photolithography alignment method and system.

According to a plurality of embodiments, a first aspect of the disclosure provides a photolithography alignment method, which can include the following operations.

Alignment measurement of a surface condition of a wafer is performed to obtain alignment information of the wafer.

The wafer is sectioned into a plurality of areas to be processed according to the alignment information, and photolithography alignment parameters corresponding to each area to be processed are determined.

According to a plurality of embodiments, a second aspect of the disclosure provides a photolithography alignment system, which can include a measurement module and a processing module.

The measurement module is configured to perform alignment measurement of a surface condition of a wafer to obtain alignment information of the wafer.

The processing module is configured to section the wafer into a plurality of areas to be processed according to the alignment information, and determine photolithography alignment parameters corresponding to each area to be processed.

Details of one or more embodiments of the disclosure will be provided in drawings and descriptions below. Other features and advantages of the disclosure will become apparent from the description, drawings and claims.

### BRIEF DESCRIPTION OF THE DRAWINGS

In order to describe the technical solutions in the embodiments of the disclosure or a conventional art more clearly, the drawings required to be used in descriptions about the embodiments or the conventional art will be simply introduced below. It is apparent that the drawings described below are only some embodiments of the disclosure. Other drawings may further be obtained by those of ordinary skilled in the art according to these drawings without creative work.

FIG. 1 is a schematic flowchart of a photolithography alignment method according to embodiments of the disclosure.

FIG. 2 is a schematic diagram of a principle of obtaining a residual value according to embodiments of the disclosure.

FIG. 3 is a schematic diagram of wafer surface signal intensity distribution according to embodiments of the disclosure.

FIG. 4 is a first schematic shape diagram of the designated areas to be processed according to embodiments of the disclosure.

FIG. 5 is a second schematic shape diagram of the designated areas to be processed according to embodiments of the disclosure.

FIG. 6 is a third schematic shape diagram of the designated areas to be processed according to embodiments of the disclosure.

FIG. 7 is a schematic diagram of an electrical structure of a photolithography alignment system according to embodiments of the disclosure.

### DETAILED DESCRIPTION

Due to the existence of the differences described in the background section, results measured with alignment marks in different areas can be different, and the alignment accuracy of the photolithography is reduced, resulting in deviations in the upper and lower layer patterns of the final photolithography, and thus resulting in the final yield loss.

In order to facilitate the understanding of this application, the disclosure will be described comprehensively below with reference to the related drawings. The drawings show embodiments of the disclosure. However, the disclosure can be implemented in various forms and is not limited to the embodiments described herein. On the contrary, these embodiments are provided to make the contents disclosed in the disclosure more thorough and comprehensive.

Unless otherwise defined, all technical and scientific terms used herein have the same meanings as commonly understood by those skilled in the art that the disclosure belongs to. Herein, terms used in the description of the disclosure are only for the purpose of describing specific embodiments and not intended to limit the disclosure.

It should be understood that, spatially relational terms such as “below”, “under”, “lower”, “beneath”, “above”, and “upper” may be used herein for describing a relationship between one element or feature and another element or feature illustrated in the figures. It is to be understood that, in addition to the orientation shown in the figures, the spatially relational terms further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower orientations. Moreover, the device may include otherwise orientation (such as rotation by 90 degrees or in other orientations) and the spatial descriptors used herein may be interpreted accordingly.

As used herein, singular forms “a/an”, “one”, and “the” may include the plural forms, unless otherwise specified types in the context. It is also to be understood that, terms such as “comprising/containing” or “having” appoint existence of declarative features, wholes, steps, operations, components, parts or combinations of them, but not excluding the possibility of existence or adding of one or more other features, wholes, steps, operations, components, parts or combinations of them. Meanwhile, in the specification, term “and/or” includes any and all combinations of the related listed items.

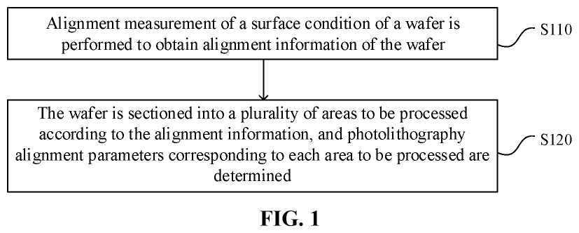

In view of the current problem that the alignment accuracy of the photolithography is relatively low due to the differences between different areas of a wafer, such as different heights of a wafer surface, different depths of embedded patterns, and different symmetry of patterns, the present application provides a photolithography alignment method. Referring to FIG. 1, the photolithography alignment method provided in the embodiment of this application can include the following operations.

At S110, alignment measurement of a surface condition of a wafer is performed to obtain alignment information of the wafer.

At S120, the wafer is sectioned into a plurality of areas to be processed according to the alignment information, and photolithography alignment parameters corresponding to each area to be processed are determined.

In the embodiment, the alignment information of the wafer is obtained by performing alignment measurement on the surface condition of the wafer before photolithography. It can be understood that, when the alignment information is the same/similar, it means that the surface conditions of two areas are also the same/similar, and the two areas can have photolithography performed thereon with the same photolithography alignment parameters. Therefore, based on obtained surface parameters of the wafer, in this embodiment, the wafer is sectioned into a plurality of areas to be processed, designates the areas with the same/similar alignment information as the same area to be processed, and determines photolithography alignment parameters of the area to be processed according to actual alignment information, so as to eliminate the influence caused by differences between different areas of the wafer, improve the photolithography alignment accuracy, and thus improve the yield of a product.

In one of the embodiments, the alignment information can include signal intensity and a residual value. It can be understood that, dozens of photolithography steps need to be used in a standard wafer processing technology. Besides the resolution of a photolithography machine, the alignment accuracy is also a very important factor affecting the photolithography process error. The residual value is an important index reflecting the alignment accuracy. Therefore, it is necessary to measure the residual values of different areas on the wafer. Moreover, when the surface conditions of the wafer are different, the signal intensity of a reflected signal is also different. Therefore, the alignment accuracy can be further improved by considering the influence of the signal intensity on the alignment accuracy at the same time, which is conducive to more reasonable division of the wafer and more reasonable setting of photolithography alignment parameters for each designated area to be processed.

In one of the embodiments, the surface of the wafer has a plurality of exposure areas, each of which has at least one alignment mark.

It can be understood that, in a chip manufacturing process, the plurality of exposure areas on the surface of the same wafer form a plurality of chips at the same time through the same process. A complete chip usually needs to be subjected to more than dozens of photolithography. In such many photolithography processes, except the first photolithography, the photolithography of other levels must align patterns of this level with the patterns left by the previous level before exposure. Therefore, at least one alignment mark needs to be set in each exposure area for alignment. Moreover, the more alignment marks are, the better the alignment accuracy is. In the embodiment, when alignment measurement on the surface condition of the wafer is performed, the obtained alignment information of the wafer can include the signal intensity of each exposure area and the residual value of each exposure area. Further, the exposure areas whose signal intensity and residual values are the same or within the same value range are designated as the same area to be processed, and a plurality of exposure areas in the same area to be processed have photolithography performed thereon by using the same photolithography alignment parameters.

In one of the embodiments, the operation that the alignment information of the wafer is obtained by performing alignment measurement on the surface condition of the wafer can include the following operations.

The alignment mark is irradiated with alignment light sources having different wavelengths to obtain the signal intensity and waveform fitting information corresponding to the alignment mark at each wavelength.

Measured position data of each alignment mark at the wavelength is determined according to the signal intensity and the waveform fitting information of the alignment mark corresponding to the same wavelength.

The residual value of the alignment mark is calculated according to the measured position data and the theoretical position data of the alignment mark.

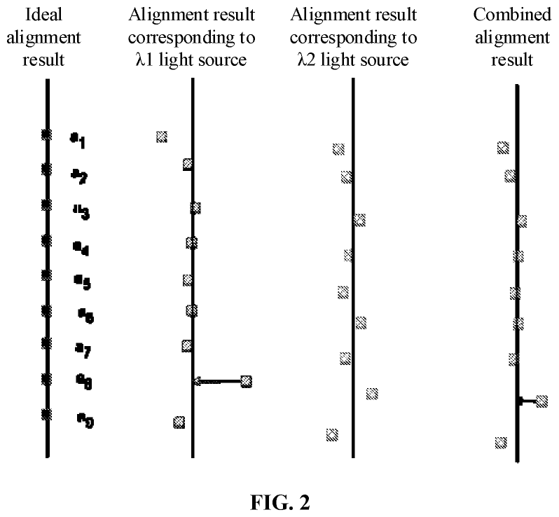

Please referring to FIG. 2, in the embodiment, the wafer is irradiated with the alignment light sources having multiple wavelengths. For example, the wafer is respectively irradiated with i alignment light sources having the wavelengths of λ_1, λ_2, λ_3 . . . . λ_I and so on. In the process of irradiating the wafer, a light beam is reflected by the wafer and incident into a detection system. The detection system obtains signal intensity and waveform fitting information corresponding to the alignment mark at each wavelength according to the reflected light beam. Afterwards, measured position data of each alignment mark at the wavelength is determined according to the signal intensity and the waveform fitting information of the alignment mark at the same wavelength. Based on this, after irradiation with i alignment light sources, each alignment mark will correspond to i pieces of measured position data. At last, i residual values corresponding to each alignment mark are obtained by calculation according to the measured position data and the theoretical position data of the alignment mark.

In one of the embodiments, the residual value of the alignment mark is a standard deviation between the measured position data of the alignment mark and the theoretical position data of the alignment mark.

In the embodiment, after irradiation with i light sources, for each alignment mark, the standard deviation between the measured position data of the alignment mark and the theoretical position data of the alignment mark is calculated, and the calculated standard deviation is the residual value of the exposure area, such as a1, a2, a9. The smaller the residual value is, the smaller the pattern offset in the exposure area is, and the higher the alignment accuracy is.

In one of the embodiments, the photolithography alignment parameters can include an alignment light source.

The operation that the surface of the wafer is sectioned into the plurality of areas to be processed according to the alignment information can include the following operations.

A plurality of residual values corresponding to the same alignment mark are compared to determine the minimum residual value among the plurality of residual values.

The alignment light source corresponding to the minimum residual value of the alignment mark is determined, and the wavelength of the alignment light source is used as the wavelength of the alignment light source required for photolithography alignment in the corresponding exposure area.

The exposure areas requiring the same alignment light source are designated as the same area to be processed, and the alignment light source of each area to be processed is determined.

In the embodiment, when different alignment light sources are used to irradiate the same exposure area, the measured position data of the alignment mark in the exposure area are also different. It can be seen that the selection of the alignment light source will also have an impact on photolithography alignment. In order to improve the alignment accuracy, the exposure areas requiring the same alignment light source are designated as the same area to be processed in the embodiment to eliminate the influence of wafer surface differences on photolithography, so as to improve the alignment accuracy.

In one of the embodiments, the photolithography alignment parameters can include the wavelength of the alignment light source and illumination intensity.

The operation that the surface of the wafer is sectioned into the plurality of areas to be processed according to the alignment information can include the following operations.

A plurality of residual values corresponding to the same alignment mark are compared to determine the minimum residual value among the plurality of residual values.

The alignment light source corresponding to the minimum residual value of the alignment mark is determined, and the wavelength of the alignment light source is used as the wavelength of the alignment light source required for photolithography alignment in the corresponding exposure area.

The plurality of exposure areas are designated according to the alignment light source, the exposure areas requiring the alignment light source with the same wavelength are designated as the same area, a plurality of primary division areas are formed, and the wavelength of the alignment light source of each primary division area is determined.

According to the signal intensity of each alignment mark, a plurality of exposure areas in the same primary division area are designated according to a preset signal intensity range to form the area to be processed, and the illumination intensity corresponding to each area to be processed is determined.

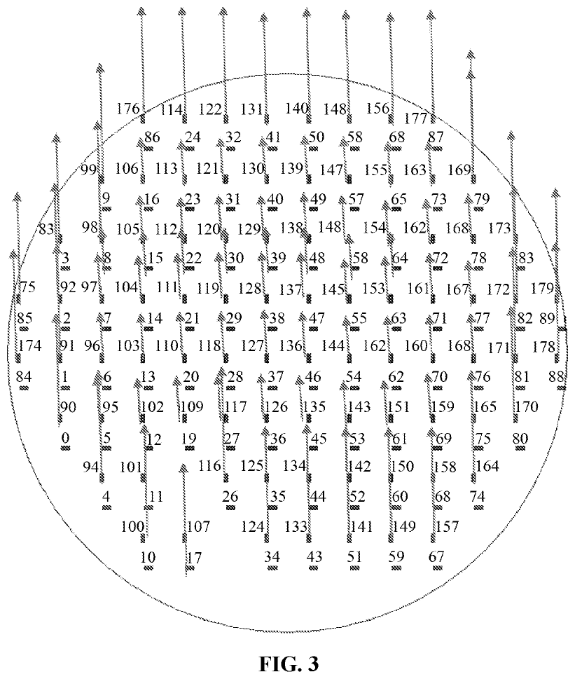

Please referring to FIG. 3, it can be seen from FIG. 3 that, the signal intensity of the alignment mark in a center area in some wafers is less than that of the alignment mark in an edge area, and the signal intensity approximately increases with the increase of the radius Therefore, the wafer is sectioned based on the residual value and the signal intensity at the same time, which can further improve the precision of division and improve the alignment accuracy. In the embodiment, all the exposure areas on the wafer are designated based on the residual value, the exposure areas requiring the alignment light source with the same wavelength are designated as the same area, a plurality of primary division areas are formed, and the wavelength of the alignment light source required by the primary division area is determined. Afterwards, according to the preset signal intensity range, a plurality of exposure areas in the same primary division area are further designated to finally form the areas to be processed, and the illumination intensity of each area to be subject to photolithography is determined. In the same areas to be processed designated based on the residual value and the signal intensity, the light source and illumination intensity required for photolithography in the exposure area are the same.

Moreover, in some other embodiments, the wafer can also be sectioned only according to the signal intensity to obtain a plurality of areas to be processed.

In one of the embodiments, the alignment information can also include waveform similarity. In the embodiment, the alignment light source is used to scan the surface of the wafer to obtain the fitting waveform corresponding to the alignment mark, and then the waveform similarity between the various alignment marks can be obtained with a similarity algorithm. The higher the waveform similarity is, the better the symmetry of the exposure area is, the smaller the offset is, and even there is no need to adjust the photolithography alignment parameters.

In the embodiment, when sectioning the wafer, the exposure areas with high waveform similarity are designated first, and then the exposure areas with poor waveform similarity are designated based on the residual values and the signal intensity, which is conducive to reducing the number of designated areas to be processed, reducing the adjustment time of photolithography alignment parameters, speeding up the photolithography process, and ensuring the alignment accuracy.

In one of the embodiments, the measured position data of the exposure area is the measured position data of the alignment mark corresponding to the strongest signal intensity determined based on the waveform fitting information.

In one of the embodiments, when the signal intensity changes regularly with the increase of the radius of the wafer, the wafer is sectioned into a plurality of annular areas to be processed.

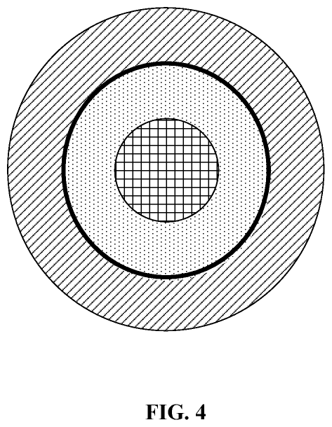

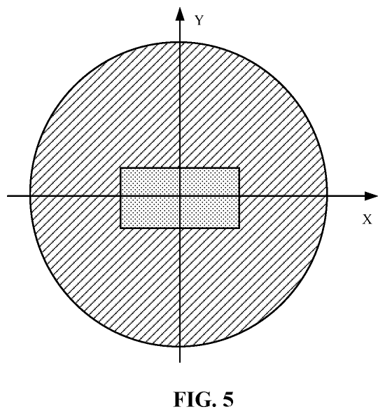

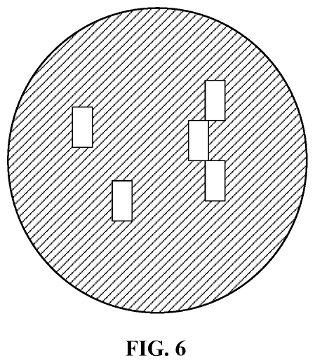

Please referring to FIG. 3 and FIG. 4 together, when the detected signal intensity changes regularly with the change of the radius, the surface of the wafer can be sectioned into a central circle and a plurality of rings according to the preset intensity range. Moreover, when the alignment information is related to coordinates, the wafer can be sectioned according to the coordinates, as shown in FIG. 5. If the data in the alignment information is irregular, the area to be processed can also be defined, as shown in FIG. 6.

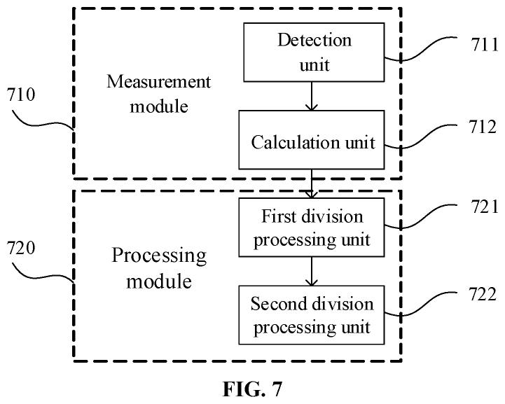

Based on the same inventive concept, the embodiment of the disclosure also provides a photolithography alignment system, please referring to FIG. 7. The photolithography alignment system can include a measurement module 710 and a processing module 720.

The measurement module 710 is configured to perform alignment measurement of a surface condition of a wafer to obtain alignment information of the wafer.

The processing module 720 is configured to section the wafer into a plurality of areas to be processed according to the alignment information and determine photolithography alignment parameters corresponding to each area to be processed.

In the embodiment, the measurement module 710 can include an irradiator, a mask support structure and a scanning device. The irradiator can include various types of optical parts for guiding, shaping or controlling radiation, such as refraction, reflection, magnetic, electromagnetic, electrostatic or other types of optical parts, or any combination thereof. The mask support structure supports (i.e., bears) the weight of a patterning device. It maintains the patterning device in a manner depending on the orientation of the patterning device, the design of a photolithography device, and other conditions (for example, whether the patterning device is maintained in a vacuum environment). The mask support structure can use mechanical, vacuum, electrostatic or other clamping techniques to maintain the patterning device. The mask support structure can be, for example, a frame or table, which can be fixed or movable as required. The mask support structure can ensure that the patterning device is in the desired position, for example, with respect to a projection system. The scanning device is configured to obtain alignment information, such as a photoelectric detector.

In one of the embodiments, the alignment information can include signal intensity and a residual value. In the embodiment, the alignment accuracy can be further improved by considering the influence of the residual value and the signal intensity on the alignment accuracy at the same time, which is conducive to more reasonable division of the wafer and more reasonable setting of photolithography alignment parameters for each designated area to be processed. Moreover, the wafer can also be sectioned separately according to the signal intensity or the residual value

In addition, in some other embodiments, the alignment information can also include waveform similarity. It can be understood that, when the wafer is sectioned, the exposure areas with high waveform similarity are designated first, and then the exposure areas with poor waveform similarity are designated based on the residual value and the signal intensity, which is conducive to reducing the number of designated areas to be processed, reducing the adjustment time of photolithography alignment parameters, speeding up the photolithography process, and ensuring the alignment accuracy.

In one of the embodiments, the surface of the wafer has a plurality of exposure areas, each of which has at least one alignment mark. The measurement module 710 can include a detection unit 711 and a calculation unit 712.

The detection unit 711 is configured to irradiate the alignment mark with alignment light sources having different wavelengths to obtain the signal intensity and waveform fitting information corresponding to the alignment mark at each wavelength.

The calculation unit 712 is configured to determine measured position data of each alignment mark at the wavelength according to the signal intensity and the waveform fitting information of the alignment mark corresponding to the same wavelength, and calculate the residual value of the alignment mark according to the measured position data and the theoretical position data of the alignment mark.

In one of the embodiments, the photolithography alignment parameters can include the wavelength of the alignment light source and illumination intensity. The processing module 720 can include a first division processing unit 721 and a second division processing unit 722.

The first division processing unit 721 is configured to compare a plurality of residual values corresponding to the same alignment mark, determine the minimum residual value among the plurality of residual values, determine the alignment light source corresponding to the minimum residual value of the alignment mark, take the wavelength of the alignment light source as the wavelength of the alignment light source required for photolithography alignment of the corresponding exposure area, designate the plurality of exposure areas according to the alignment light source, designate the exposure areas requiring the alignment light source with the same wavelength as the same area, form a plurality of primary division areas, and determine the wavelength of the alignment light source of each primary division area.

The second division processing unit 722 is configured to designate a plurality of exposure areas in the same primary division area according to the signal intensity of each alignment mark and a preset signal intensity range to form the areas to be processed, and determine the illumination intensity corresponding to each area to be processed.

In the embodiment, the calculation unit 712, the first division processing unit 721 and the second division processing unit 722 can be integrated in the same chip, such as intelligent chips of a Microcontroller Unit (MCU), a Central Processing Unit (CPU), a Digital Signal Processing (DSP) or a Field Programmable Gate Array (FPGA).

In descriptions of the specification, description of referring terms such as “one embodiment” and “other embodiments” refers to specific features, structures, materials or features described in combination with the embodiments or demonstrations involved in at least one embodiment or demonstration of the disclosure. In the specification, schematic description on the above terms not always refers to same embodiments or demonstrations.

In some embodiments, the various modules and units mentioned in the present disclosure may be hardware components.

Each technical feature of the above mentioned embodiments may be combined freely. For simplicity of description, not all possible combinations of each technical solution in the above mentioned embodiments are described. However, any combination of these technical features shall fall within the scope recorded in the specification without conflicting.

The above-mentioned embodiments only express some implementation modes of the disclosure and are specifically described in detail and not thus understood as limits to the patent scope of the disclosure. It is to be pointed out that those of ordinary skill in the art may further make a plurality of transformations and improvements without departing from the concept of the disclosure and all of these shall fall within the scope of protection of the disclosure. Therefore, the scope of patent protection of the disclosure should be subject to the appended claims.

What is claimed is:

1. A photolithography alignment method, comprising:
performing alignment measurement of a surface condition of a wafer to obtain alignment information of the wafer; and
sectioning the wafer into a plurality of areas to be processed according to the alignment information, and determining photolithography alignment parameters corresponding to each area to be processed.

2. The photolithography alignment method according to claim 1, wherein the alignment information comprises a signal intensity and a residual value.

3. The photolithography alignment method according to claim 2, wherein a surface of the wafer has a plurality of exposure areas, each exposure areas having at least one alignment mark.

4. The photolithography alignment method according to claim 3, wherein the performing alignment measurement of a surface condition of a wafer to obtain alignment information of the wafer comprises:
irradiating the alignment mark with alignment light sources having different wavelengths to obtain signal intensity and waveform fitting information corresponding to the alignment mark at each wavelength;
determining measured position data of each alignment mark at the wavelength according to the signal intensity and the waveform fitting information of the alignment mark corresponding to a same wavelength; and
calculating the residual value of the alignment mark according to the measured position data and the theoretical position data of the alignment mark.

5. The photolithography alignment method according to claim 4, wherein the photolithography alignment parameters comprise wavelengths of alignment light sources;
the sectioning surface of the wafer into a plurality of areas to be processed according to the alignment information comprises:
comparing a plurality of residual values corresponding to a same alignment mark to determine a minimum residual value among the plurality of residual values;
determining the alignment light source corresponding to the minimum residual value of the alignment mark, and taking the wavelength of the alignment light source as the wavelength of the alignment light source required for photolithography alignment in the corresponding exposure area; and
allocating the exposure areas requiring the same alignment light source to the same areas to be processed, and determining the alignment light source of each area to be processed.

6. The photolithography alignment method according to claim 4, wherein the photolithography alignment parameters comprise wavelengths of alignment light sources and illumination intensity;
the sectioning surface of the wafer into a plurality of areas to be processed according to the alignment information further comprises:
comparing a plurality of residual values corresponding to a same alignment mark to determine a minimum residual value among the plurality of residual values;
determining the alignment light source corresponding to the minimum residual value of the alignment mark, and taking the wavelength of the alignment light source as the wavelength of the alignment light source required for photolithography alignment in the corresponding exposure area;
designating the plurality of exposure areas according to the alignment light source, designating exposure areas requiring the alignment light source with a same wavelength to a same area to form a plurality of primary division areas, and determining the wavelength of the alignment light source of each primary division area; and
based on the signal intensity of each alignment mark, designating a plurality of exposure areas in a same primary division area according to a preset signal intensity range to form the areas to be processed, and determining the illumination intensity corresponding to each area to be processed.

7. The photolithography alignment method according to claim 4, wherein the measured position data of the exposure area is the measured position data of the alignment mark corresponding to a strongest signal intensity determined based on the waveform fitting information.

8. The photolithography alignment method according to claim 4, wherein the residual value of the alignment mark is a standard deviation between the measured position data of the alignment mark and the theoretical position data of the alignment mark.

9. The photolithography alignment method according to claim 2, wherein when the signal intensity changes regularly with an increase of a radius of the wafer, the wafer is sectioned into a plurality of annular areas to be processed.

10. The photolithography alignment method according to claim 2, wherein the sectioning the surface of the wafer into a plurality of areas to be processed according to the alignment information comprises:
designating exposure areas each having a signal intensity and a residual value that are same or within a same value range as a same area to be processed.

11. The photolithography alignment method according to claim 4, wherein the alignment information further comprises waveform similarity.

12. The photolithography alignment method according to claim 11, wherein the obtaining the alignment information of the wafer comprises:
scanning the surface of the wafer by using the alignment light source to obtain the fitting waveform corresponding to the alignment mark, and then obtaining the waveform similarity between the various alignment marks with a similarity algorithm.

13. A photolithography alignment system, comprising:
a measurement component, configured to perform alignment measurement of a surface condition of a wafer to obtain alignment information of the wafer; and
a processing component, configured to section the wafer into a plurality of areas to be processed according to the alignment information, and determine photolithography alignment parameters corresponding to each area to be processed.

14. The photolithography alignment system according to claim 13, wherein the alignment information comprises a signal intensity and a residual value.

15. The photolithography alignment system according to claim 14, wherein the surface of the wafer has a plurality of exposure areas, each having at least one alignment mark, and the measurement component comprises:
a detection component, configured to irradiate the alignment mark with alignment light sources having different wavelengths to obtain signal intensity and waveform fitting information corresponding to the alignment mark at each wavelength; and
a calculation component, configured to determine measured position data of each alignment mark at the wavelength according to the signal intensity and the waveform fitting information of the alignment mark corresponding to a same wavelength, and calculate the residual value of the alignment mark according to the measured position data and the theoretical position data of the alignment mark.

16. The photolithography alignment system according to claim 15, wherein the photolithography alignment parameters comprise wavelengths of alignment light sources; and the processing component is further configured to:
compare a plurality of residual values corresponding to the same alignment mark to determine the minimum residual value among the plurality of residual values;
determine the alignment light source corresponding to the minimum residual value of the alignment mark, and take the wavelength of the alignment light source as the wavelength of the alignment light source required for photolithography alignment in the corresponding exposure area; and
allocate exposure areas requiring a same alignment light source to a same area to be processed, and determine the alignment light source of each area to be processed.

17. The photolithography alignment system according to claim 15, wherein the photolithography alignment parameters comprise wavelengths of alignment light sources and illumination intensity; and the processing component comprises:
a first division processing component, configured to compare a plurality of residual values corresponding to the same alignment mark, determine the minimum residual value among the plurality of residual values, determine the alignment light source corresponding to the minimum residual value of the alignment mark, take the wavelength of the alignment light source as the wavelength of the alignment light source required for photolithography alignment of the corresponding exposure area, section the plurality of exposure areas according to the alignment light source, allocate exposure areas requiring the alignment light source with the same wavelength to a same area, form a plurality of primary division areas, and determine the wavelength of the alignment light source of each primary division area; and
a second division processing component, configured to, based on the signal intensity of each alignment mark, designate a plurality of exposure areas in a same primary division area according to a preset signal intensity range to form the areas to be processed, and determine the illumination intensity corresponding to each area to be processed.

18. The photolithography alignment system according to claim 15, wherein the measured position data of the exposure area is the measured position data of the alignment mark corresponding to a strongest signal intensity determined based on the waveform fitting information.

19. The photolithography alignment system according to claim 15, wherein the residual value of the alignment mark is a standard deviation between the measured position data of the alignment mark and a theoretical position data of the alignment mark.

20. The photolithography alignment system according to claim 13, wherein when the signal intensity changes regularly with an increase of a radius of the wafer, the wafer is sectioned into a plurality of annular areas to be processed.
